(19) United States
(12) Patent Application Publication
(10) Pub. No.: US 2023/0081711 A1
(43) Pub. Date: Mar. 16, 2023

(54) WIRE BONDING TOOL

(71) Applicant: STMicroelectronics (Grenoble 2) SAS, Grenoble (FR)

(72) Inventors: Didier CAMPOS, Charavines (FR); Fabien QUERCIA, Saint Marcelin (FR); Justin CATANIA, Grenoble (FR)

(73) Assignee: STMicroelectronics (Grenoble 2) SAS, Grenoble (FR)

(21) Appl. No.: 17/943,885

(22) Filed: Sep. 13, 2022

(30) Foreign Application Priority Data
Sep. 15, 2021 (FR) 2109675

(51) Int. Cl. B23K 20/00; B23K 20/10

(52) U.S. Cl. CPC B23K 20/007; B23K 20/10; B23K 2101/36

(57) ABSTRACT

A wire bonding tool includes a tool body with a tubular cavity extending through the tool body and a distal end. The distal end includes a flared opening at an end of the tubular cavity. The tool body further includes at least one protrusion at a level of the distal end.

### PRIORITY CLAIM

This application claims the priority benefit of French Application for Patent No. 2109675, filed on Sep. 15, 2021, the content of which is hereby incorporated by reference in its entirety to the maximum extent allowable by law.

### TECHNICAL FIELD

The present disclosure generally concerns electronic contact connection techniques. The present disclosure more particularly applies to wire bonding techniques.

### BACKGROUND

There exist different techniques enabling to connect, to one another, contacts of electronic components and/or connection pads of printed circuit boards.

Among these different techniques, the wire bonding technique is an efficient technique enabling to link with an electrically-conductive wire, preferably a metal wire, a plurality of contacts or connection pads.

It would be desirable to be able to at least partly improve certain aspects of known connection techniques and, in particular, certain aspects of known wire bonding techniques.

There is a need for a wire bonding technique adapted to more efficiently connecting connection pads.

There is a need for a wire bonding technique adapted to forming stronger connections.

### SUMMARY

An embodiment overcomes all or part of the disadvantages of known wire bonding techniques and known wire bonding technique tools.

An embodiment provides a wire bonding tool comprising at the level of one of its ends at least one protrusion.

According to an embodiment, said at least one protrusion has a rectangular cross-section.

According to an embodiment, the rectangular cross-section has a width in the range from 5 to 10 μm.

According to an embodiment, the rectangular cross-section has a length in the range from 5 to 10 μm.

According to an embodiment, the tool comprises at least two protrusions.

According to an embodiment, said at least two protrusions are parallel to one another.

According to an embodiment, said end is an end comprising an opening adapted to letting out a wire.

According to an embodiment, the tool further comprises a tubular cavity.

According to an embodiment, the tubular cavity has a round cross-section.

According to an embodiment, the tubular cavity has an oval cross-section.

According to an embodiment, the tool further comprises heating means.

According to an embodiment, the tool further comprises means for generating an ultrasound wave.

Another embodiment provides a wire bonding method using the previously-described wire bonding tool.

### BRIEF DESCRIPTION OF THE DRAWINGS

The foregoing features and advantages, as well as others, will be described in detail in the following description of specific embodiments given by way of illustration and not limitation with reference to the accompanying drawings, in which:

FIG. 1 shows a partial cross-section view of an embodiment of a wire bonding tool;

FIG. 2 shows a cross-section view of a step of an implementation mode of a wire bonding method using the tool of FIG. 1;

FIG. 3 shows another step of an implementation mode of a wire bonding method using the tool of FIG. 1;

FIG. 4 shows another step of an implementation mode of a wire bonding method using the tool of FIG. 1; and

FIG. 5 shows another step of an implementation mode of a wire bonding method using the tool of FIG. 1.

### DETAILED DESCRIPTION

Like features have been designated by like references in the various figures. In particular, the structural and/or functional features that are common among the various embodiments may have the same references and may dispose identical structural, dimensional and material properties.

For the sake of clarity, only the steps and elements that are useful for an understanding of the embodiments described herein have been illustrated and described in detail.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following disclosure, unless otherwise specified, when reference is made to absolute positional qualifiers, such as the terms “front”, “back”, “top”, “bottom”, “left”, “right”, etc., or to relative positional qualifiers, such as the terms “above”, “below”, “upper”, “lower”, etc., or to qualifiers of orientation, such as “horizontal”, “vertical”, etc., reference is made to the orientation shown in the figures.

Unless specified otherwise, the expressions “around”, “approximately”, “substantially” and “in the order of” signify within 10%, and preferably within 5%.

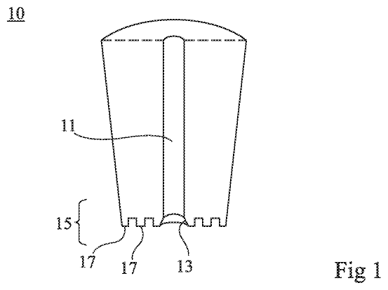

FIG. 1 is a partial cross-section view of an embodiment of a wire bonding tool 10. This view shows the capillary of tool 10, that is, the tip of tool 10 which is directed towards the connection pads to be connected. In the rest of the description, the portion of tool 10 shown in FIG. 1 is indifferently referred to as a tool 10 and a capillary of the tool 10.

The body of the capillary of wire bonding tool 10 has a substantially elongated and tubular shape, for example, a substantially frustoconical shape, and comprises a tubular cavity 11 at its center configured to containing a bonding wire (not shown in FIG. 1). Cavity 11, for example, extends completely through the capillary of tool 10, or for example all along the capillary of tool 10, and emerges onto an opening configured to let out the bonding wire. As an example, the capillary of tool 10 is, in cross-section view, of substantially frustoconical tubular shape and, in bottom view (not shown), of circular shape. As an example, cavity 11 may flare at the level of the end of tool 10. The cavity 11 of wire bonding tool 10 is of tubular shape with a circular, oval, or oblong cross-section. As a variant, cavity 11 is of tubular shape with a circular cross-section, and has a surface that is flared outwardly at the end 13 into a circular, oval, or oblong shape. The flared surface of the extends from an end of the tubular cavity 11.

According to an embodiment, tool 10 comprises, at the level of its end 15, at least one protrusion 17, preferably a plurality of protrusions 17. End 15 is the end of the capillary of tool 10 which has the bonding wire coming out of it during the implementation of tool 10. In other words, end 15 is the end of the tip of tool 10. According to an example, the capillary of tool 10 and its end 15 are made of ceramic. The flared surface of the end 13 forms a lateral surface of an innermost one of the protrusions 17.

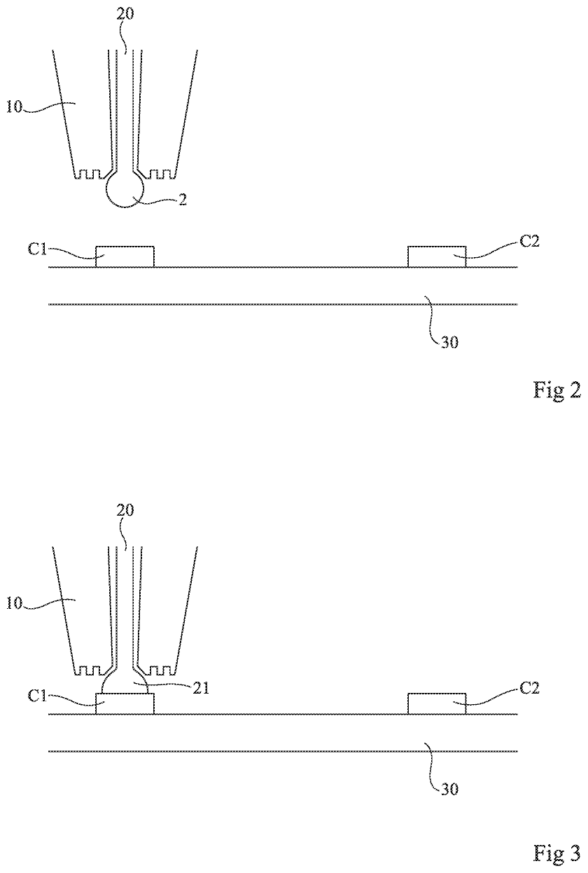

According to an example, tool 10 comprises from 1 to 3 protrusions 17. Protrusion(s) 17 are arranged at the level of end 15 to protrude from the end of the tool 10 in a direction parallel to the main direction of tool 10, the vertical direction in FIG. 1 or the direction in which the cavity 11 extends. Protrusion(s) 17 enable to more efficiently crush the bonding wire on implementation of a wire bonding method. The implementation of such a method is described in further detail in relation with FIGS. 2 to 5. According to an example, protrusion(s) 17 are created from grooves formed at the level of end 15. According to an example, in the case of a plurality of protrusions 17, protrusions 17 are substantially parallel to one another. According to an example, when the capillary of tool 10 is sized for a wire having a diameter in the order of 20 μm, end 15 has a width in the order of 100 μm. Protrusion(s) 17, for example, have a rectangular, or even square, cross-section and form, in cross-section view, a crenellated shape. Protrusion(s) 17, for example, have a width in the range from 5 to 10 μm and a length in the range from 5 to 10 μm. More generally, protrusion(s) 17 have a width and a length smaller than the diameter of the bonding wire for which tool 10 is sized.

Tool 10 comprises a heating element (not shown in FIG. 1) enabling to melt the bonding wire and thus to form a bonding ball. More particularly, the element for heating the wire, for example, is an electrode attached to tool 10.

Tool 10 further comprises means for bonding the wire (not shown in FIG. 1). More particularly, the means for bonding the wire are elements emitting an ultrasound vibration in tool 10 and which, by addition of a force towards the connection pad, allow the bonding between the wire and the connection pad.

A tool of this type is generally attached to a mobile arm of a displacement device enabling to accurately position it above a connection pad arranged on a printed circuit board.

A bonding wire configured for use with tool 10 is made of a metal or of an alloy of metals. As an example, the wire is made of gold. The wire has a diameter conforming to the dimensions of cavity 3. As an example, the wire has a diameter in the range from 15 to 30 μm, for example, in the range from 18 to 25 μm, for example, in the order of approximately 20 μm. According to another example, the wire may have a diameter in the order of 50 μm.

FIGS. 2 to 5 are partial simplified cross-section views of steps of an implementation mode of a wire bonding method using the embodiment of tool 10 described in relation with FIG. 1.

More particularly, FIGS. 2 to 5 show successive steps of a method of wire bonding of two connection pads C1 and C2 with a bonding wire 20. Bonding wire 20 is of the type of the bonding wire described in relation with FIG. 1. As in FIG. 1, only the capillary of tool 10 is shown.

As an example, connection pads C1 and C2 are arranged on a substrate 30, but as a variant, the contacts may be contacts of components directly arranged thereon, these components for example being bonded to a printed circuit board. Substrate 30 is, for example, a semiconductor substrate, for example made of silicon. Connection pads C1 and C2 are made of a conductive material, for example a metal or of an alloy of metals.

At the step of FIG. 2, tool 10 is positioned above connection pad C1, for example, via a mobile arm of a displacement device. The heating element of tool 10 heats the end of bonding wire 20. Accordingly, a ball 21 forms at the end of wire 20. The heating element is then deactivated.

At the step of FIG. 3, the bonding means of tool 10 are activated and tool 10 is pressed towards connection pad C1 so that ball 5A is crushed and welded onto connection pad C1.

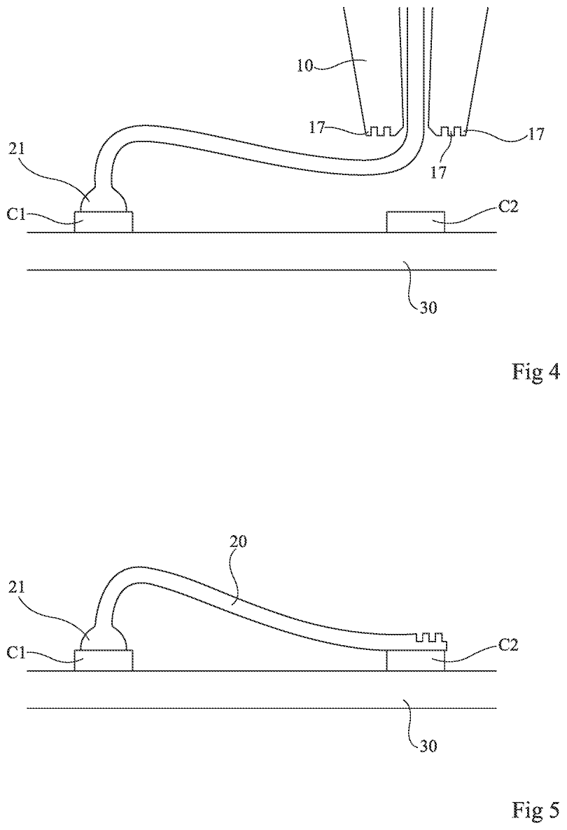

At the step of FIG. 4, tool 10 is raised and displaced, for example, via the mobile arm, to be positioned above connection pad C2. Bonding wire 20 then has an end bonded to connection pad C1. A portion of wire 20 is then positioned between connection pads C1 and C2.

At the step of FIG. 5, the means for bonding tool 10 are activated and tool 10 (not shown) is pressed towards connection pad C2 to crush and weld wire 20 onto connection pad C2. At this step, protrusions 17 take part in the crushing of wire 20 onto connection pad C2. As an illustration, protrusions 17 leave an impression on the portion of wire 20 crushed on connection pad C2.

Wire 20 is cut, or broken, just after this second bonding step. The wire bonding method is then ended and connection pads C1 and C2 are connected to each other via a portion of bonding wire 20.

The tool heating element can then be reactivated afterwards to form a new ball at the end of wire 20. The method is then repeated as needed.

An advantage of the use of a wire bonding tool of the type of the tool 10 described herein is that it allows a better bonding by crushing of a bonding wire on a connection pad. More particularly, the tool enables to form a more robust adhesion of the bonding wire onto the connection pad.

Another advantage is that the use of a bonding tool may enable to decrease the mechanical force applied by the wire bonding tool during the crushing of the wire on the connection pad.

Further, another advantage of this embodiment is that it does not modify the conventional wire bonding method and that it can adapt on already-existing wire bonding tools.

Various embodiments and variants have been described. Those skilled in the art will understand that certain features of these various embodiments and variants may be combined, and other variants will occur to those skilled in the art.

Finally, the practical implementation of the described embodiments and variations is within the abilities of those skilled in the art based on the functional indications given hereabove.

1. A wire bonding tool, comprising:
a tool body having a distal end;
wherein the tool body further includes at least one protrusion extending at a level of said distal end.

2. The tool according to claim 1, wherein said at least one protrusion has a rectangular cross-section.

3. The tool according to claim 2, wherein the rectangular cross-section has a width in a range from 5 to 10 μm.

4. The tool according to claim 2, wherein the rectangular cross-section has a length in a range from 5 to 10 μm.

5. The tool according to claim 1, comprising at least two protrusions.

6. The tool according to claim 5, wherein said at least two protrusions are parallel to one another.

7. The tool according to claim 1, wherein the tool body further includes, at said distal end, a flared opening configured to let out a bonding wire.

8. The tool according to claim 7, further comprising a tubular cavity coupled to said flared opening and extending through the tool body.

9. The tool according to claim 8, wherein the tubular cavity has a round cross-section.

10. The tool according to claim 8, wherein the tubular cavity has an oval cross-section.

11. The tool according to claim 7, wherein a surface of said flared opening forms a lateral surface of an innermost protrusion of said at least one protrusion.

12. The tool according to claim 1, further comprising a heating element.

13. The tool according to claim 1, further comprising an ultrasound element configured to apply an ultrasonic wave.

14. A wire bonding tool, comprising:
a tool body having a distal end;
a tubular cavity extending through the tool body to said distal end;
wherein the tubular cavity has an oval cross-section; and
wherein the tool body further includes at least one protrusion extending at a level of said distal end.

15. The tool according to claim 14, wherein the tool body further includes, at said distal end, a flared opening for the tubular cavity.

16. The tool according to claim 15, wherein a surface of said flared opening forms a lateral surface of an innermost protrusion of said at least one protrusion.

17. The tool according to claim 14, further comprising a heating element.

18. The tool according to claim 14, further comprising an ultrasound element configured to apply an ultrasonic wave.
